(19) United States
(12) Patent Application Publication
(10) Pub. No.: US 2024/0380388 A1
(43) Pub. Date: Nov. 14, 2024

(54) FILTER PROCESSING DEVICE, FILTER PROCESSING METHOD, COMMUNICATION SYSTEM, AND RECORDING MEDIUM

(71) Applicant: NEC Corporation, Minato-ku, Tokyo (JP)

(72) Inventor: Eita Kobayashi, Tokyo (JP)

(73) Assignee: NEC Corporation, Minato-ku, Tokyo (JP)

(21) Appl. No.: 18/574,485

(22) PCT Filed: Jul. 2, 2021
(86) PCT No.: PCT/JP2021/025091

§ 371 Date: Dec. 27, 2023

(51) Int. Cl. H03H 17/02

(52) U.S. Cl. CPC H03H 17/0213

(57) ABSTRACT

A filter processing device that includes an address control unit that specifies, based on the offset amount of a light source frequency and a subcarrier center point for each subcarrier, a write address and a read address for a plurality of items of data included in Fourier transform data based on an optical signal, and a storage unit in which a plurality of items of data are written to the write address specified by the address control unit and in which data is read out from the read address specified by the address control unit. The address control unit specifies the write address and the read address so that compensation for the offset amount and separation of the subcarrier are performed by the same storage unit.

### TECHNICAL FIELD

The present disclosure relates to a filter device or the like used for optical communication.

### BACKGROUND ART

Multi-subcarrier communication has been developed to cope with longer distances and larger capacities of optical communication. In multi-subcarrier communication, optical communication is performed using a plurality of carrier waves called subcarriers. Therefore, in the multi-subcarrier communication, it is necessary to separate the subcarriers from optical signals used for optical communication.

PTL 1 discloses a communication device that transmits a plurality of optical signals by frequency multiplex. The device of PTL 1 sets the transmission band of the light filter unit in accordance with the signal band of the transmission signal after experiencing the band narrowing in the transmission line to the communication device on the receiving end. The device of PTL 1 inputs a transmission signal before transmission to the light filter unit to limit the signal band and transmits a transmission signal with a limited signal band.

### CITATION LIST

### Patent Literature

### SUMMARY OF INVENTION

### Technical Problem

In the method of PTL 1, a dedicated storage unit is required to perform subcarrier separation. If the dedicated storage unit is arranged to perform subcarrier separation, a circuit scale and power consumption increase. Therefore, a technique is required for performing subcarrier separation without adding a dedicated storage unit.

A purpose of the present disclosure is to provide a filter processing device or the like that may perform subcarrier separation without adding a dedicated storage unit.

### Solution to Problem

A filter processing device of an aspect of the present disclosure includes an address control unit that specifies, based on the offset amount of a light source frequency and a subcarrier center point for each subcarrier, a write address and a read address for a plurality of items of data included in Fourier transform data based on an optical signal, and a storage unit in which a plurality of items of data are written to the write address specified by the address control unit and in which data is read out from the read address specified by the address control unit. The address control unit specifies the write address and the read address so that compensation for the offset amount and separation of the subcarrier are performed by the same storage unit.

A filter processing method of an aspect of the present disclosure executed by a computer includes specifying in a storage unit, based on an offset amount of a light source frequency and a subcarrier center point for each subcarrier, a write address and a read address for a plurality of items of data included in Fourier transform data based on an optical signal so that compensation for the offset amount and separation of the subcarrier are performed by the same storage unit; writing the plurality of items of data to the specified write address of the storage unit; and reading out the data from the specified read address of the storage unit.

A program of an aspect of the present disclosure causes a computer to execute a process of specifying in a storage unit, based on an offset amount of a light source frequency and a subcarrier center point for each subcarrier, a write address and a read address for a plurality of items of data included in Fourier transform data based on an optical signal so that compensation for the offset amount and separation of the subcarrier are performed by a same storage unit; a process of writing the plurality of items of data to the specified write address of the storage unit; and a process of reading out the data from the specified read address of the storage unit.

### Advantageous Effects of Invention

According to the present disclosure, it may be possible to provide a filter processing device or the like that may perform subcarrier separation without adding a dedicated storage unit.

### BRIEF DESCRIPTION OF DRAWINGS

FIG. 1 is a block diagram illustrating an example of a configuration of a communication system according to a first example embodiment.

FIG. 2 is a schematic diagram illustrating an example of Fast Fourier Transform (FFT) data input to the filter processing device according to the first example embodiment.

FIG. 3 is a schematic diagram for illustrating a light source frequency offset compensation processing performed by the filter processing device according to the first example embodiment.

FIG. 4 is a schematic diagram for illustrating a subcarrier separation processing performed by the filter processing device according to the first example embodiment.

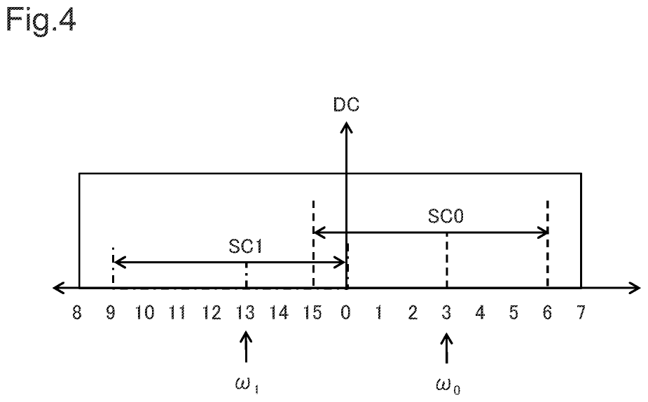

FIG. 5 is a schematic diagram for illustrating data array before and after offset compensation processing and subcarrier separation processing by the filter processing device according to the first example embodiment.

FIG. 6 is a flowchart for illustrating an example of an operation by the filter processing device according to the first example embodiment.

FIG. 7 is a block diagram illustrating an example of a configuration of a filter processing device according to related technology 1.

FIG. 8 is a schematic diagram for illustrating data array before and after offset compensation processing by the filter processing device according to related technology 1.

FIG. 9 is a schematic diagram for illustrating data array before and after subcarrier separation processing by the filter processing device according to related technology 1.

FIG. 10 is a block diagram illustrating an example of a configuration of a communication system according to a second example embodiment.

FIG. 11 is a block diagram of an example of a configuration of a coefficient arithmetic processing unit of the filter processing device according to the second example embodiment.

FIG. 12 is a flowchart for illustrating an example of an operation of the filter processing device according to the second example embodiment.

FIG. 13 is a block diagram illustrating an example of a configuration of a filter processing device according to related technology 2.

FIG. 14 is a schematic diagram for illustrating a compensation factor used in compensation processing other than the offset compensation processing and subcarrier separation processing by the filter processing device according to the second example embodiment.

FIG. 15 is a block diagram of an example of a configuration of a communication system according to a third example embodiment.

FIG. 16 is a block diagram illustrating an example of a configuration of a storage unit of the filter processing device according to the third example embodiment.

FIG. 17 is a block diagram illustrating an example of an internal configuration of a partial storage unit included in the storage unit of the filter processing device according to the third example embodiment.

FIG. 18 is a schematic diagram for illustrating offset compensation processing performed by the filter processing device according to the third example embodiment.

FIG. 19 is a schematic diagram for illustrating data array before and after offset compensation processing and subcarrier separation processing by the filter processing device according to the third example embodiment.

FIG. 20 is a schematic diagram for illustrating an example of writing data into a plurality of partial storage units included in the storage unit of the filter processing device according to the third example embodiment.

FIG. 21 is a schematic diagram for illustrating another example of writing data into the plurality of partial storage units included in the storage unit of the filter processing device according to the third example embodiment.

FIG. 22 is a schematic diagram for illustrating an example of reading out data from the plurality of partial storage units included in the storage unit of the filter processing device according to the third example embodiment.

FIG. 23 is a block diagram illustrating an example of a configuration of a filter processing device according to a fourth example embodiment.

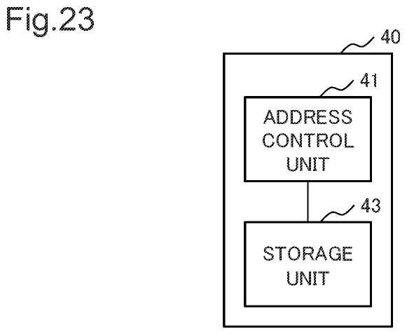

FIG. 24 is a block diagram illustrating an example of a hardware configuration that achieves the control and processing of the filter processing device according to each example embodiment.

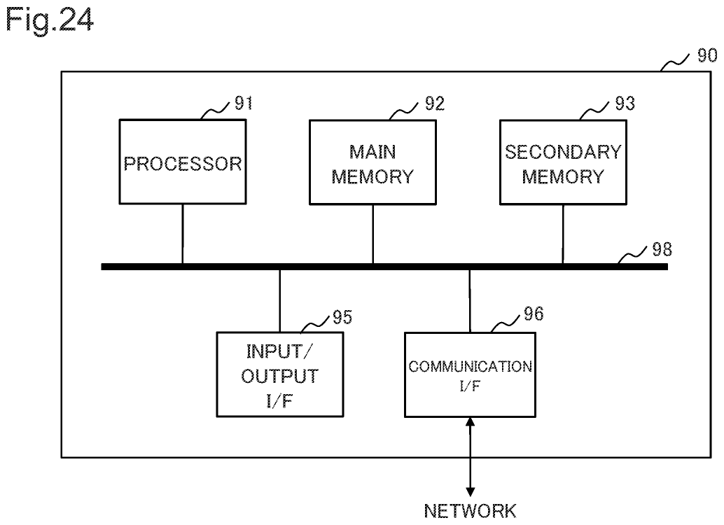

### EXAMPLE EMBODIMENTS

Hereinafter, example embodiments of the present invention will be described with reference to the drawings. However, the example embodiments described below have technically preferable limitations for carrying out the present invention, but the scope of the invention is not limited to the following. In all the drawings used in the following description of the example embodiments, the same reference numerals are given to the same parts unless otherwise specified. Further, in the following example embodiments, repeated description of similar configurations and operations may be omitted.

### First Example Embodiment

First, a communication system according to a first example embodiment will be described with reference to the drawings. The communication system of the present example embodiment is used for optical communication. The communication system of the present example embodiment performs offset compensation processing and subcarrier separation processing on digital data (hereinafter, also referred to as data) subjected to the fast Fourier transform (FFT) processing. In the present example embodiment, focusing attention on the offset compensation processing and subcarrier separation processing, filter processing that is typically performed will be omitted.

### (Configuration)

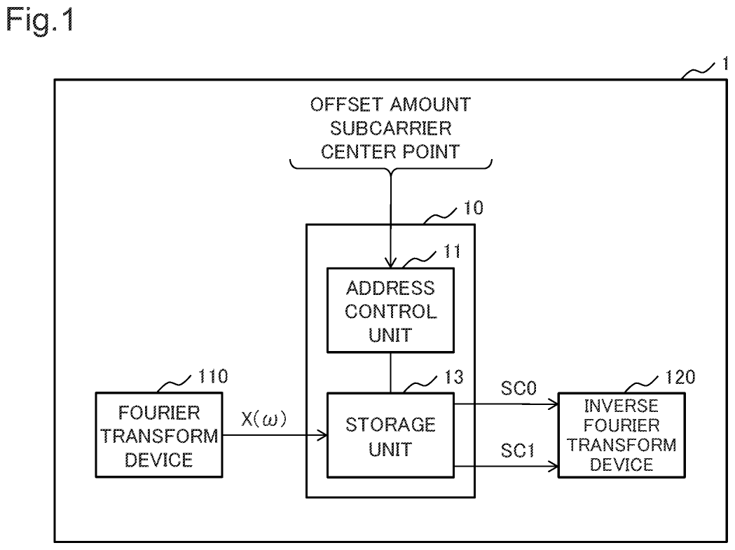

FIG. 1 is a block diagram illustrating an example of a configuration of a communication system 1 of the present example embodiment. The communication system 1 includes a Fourier transform device 110, a filter processing device 10, and an inverse Fourier transform device 120. The filter processing device 10 is connected to the Fourier transform device 110 and inverse Fourier transform device 120.

The Fourier transform device 110 performs FFT processing on the signal in the time domain subjected to analog digital (AD) conversion to convert the signal into data (also referred to as FFT data) in the frequency domain. The Fourier transform device 110 outputs the FFT data to the filter processing device 10.

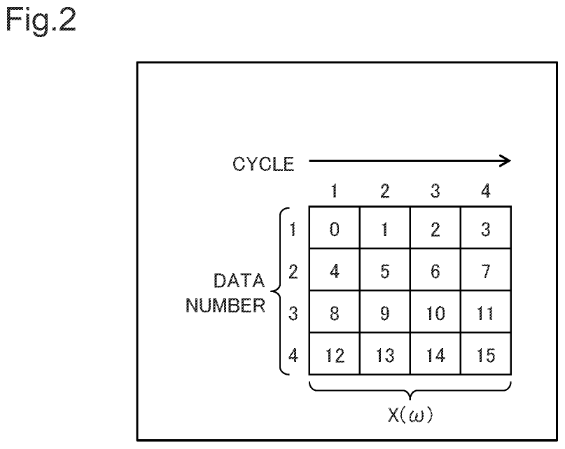

FIG. 2 is a schematic diagram for illustrating the FFT data X(ω) input to the filter processing device 10. In the example of FIG. 2, the FFT data X(ω) includes 16 items of discrete data. One cycle includes four items of data. A data number of 1 to 4 is provided to data for each cycle. In the example of FIG. 2, the number of 0 to 15 (also referred to as a sample number) is provided to 16 items of data included in the FFT data X(ω) before being rearranged. Hereinafter, a sample number is provided to each of a plurality of items of data based on the data arrangement in the FFT data X(ω) before being rearranged. The sample number is provided in accordance with the data frequency. For example, the data of data number 2 in cycle 2 is represented as data 5. Even after the data constituting FFT data X(ω) is rearranged, the sample number provided to the data is maintained as it is. Although the present example embodiment provides an example in which 16 items of data constitutes the FFT data X(ω), the number of items of data constituting the FFT data X(ω) is not particularly limited. When, for example, 256 items of data are processed in parallel in 16 cycles, the number of items of data is 4096.

The filter processing device 10 includes an address control unit 11 and a storage unit 13. 16 items of data constituting the FFT data X(ω) are input in parallel in four cycles to the filter processing device 10. In the example of FIG. 2, data 0, data 4, data 8, and data 12 are input to the filter processing device 10 input in the first cycle. In the second cycle, data 1, data 5, data 9, and data 13 are input to the filter processing device 10 input. In the third cycle, data 2, data 6, data 10, and data 14 are input to the filter processing device 10. In the fourth cycle, data 3, data 7, data 11, and data 15 are input to the filter processing device 10. The data input to the filter processing device 10 is addressed by the address control unit 11 and stored in the storage unit 13. The data input to the filter processing device 10 is stored in the write address specified by the address control unit 11. The data stored in the storage unit 13 is read out from the read address specified by the address control unit 11.

The address control unit 11 is input with an offset amount based on a transmission frequency (also referred to as a light source frequency) of a local light source of the communication system 1 including the filter processing device 10. For example, the offset amount is input to the address control unit 11 via an input device (not shown). The offset amount may be registered in advance in the address control unit 11. In addition, the offset amount may also be configured to be estimated by an offset estimation circuit (not shown).

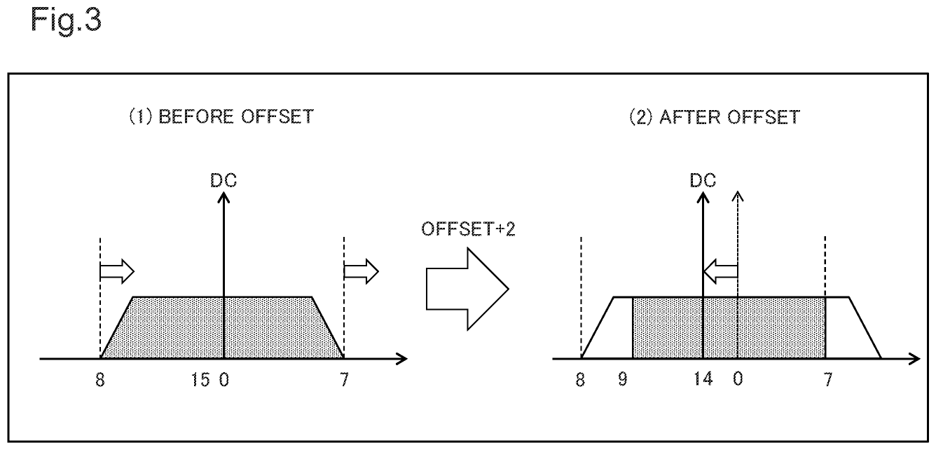

FIG. 3 is a schematic diagram for illustrating light source frequency offset compensation processing. The plurality of items of data constituting the FFT data X(ω) is distributed around data 0 of a direct current (DC) component having the strongest intensity. The order of the compensation processing before offset (1) is the order of data 0, data 1, data 2, . . . , data 14, and data 15. The offset amount of the signal input to the filter processing device 10 is compensated in accordance with—the light source frequency of the communication system 1. In the example of FIG. 3, the offset amount is +2. The order of the compensation processing after offset (2) is the order of data 14, data 15, data 0, . . . , data 12, and data 13. In the example of FIG. 3, the signal value of data with low intensity (data 7, data 8, data 9) is set to 0. Setting the signal value of unnecessary data to 0 is also referred to as 0 filling.

In addition, a center point (referred to as a subcarrier center point) for each subcarrier is input to the address control unit 11. For example, the subcarrier center point is input via an input device (not shown). The subcarrier center point may be registered in advance in the address control unit 11. Although the present example embodiment provides an example using two subcarriers, the number of subcarrier is not particularly limited.

FIG. 3 is a schematic diagram for illustrating subcarriers included in the FFT data X(ω). The FFT data X(ω) includes subcarrier data SC0 and subcarrier data SC1. Subcarrier data SC0 includes eight items of data (15, 0, 1, 2, 3, 4, 5, 6) before and after (−4, +3) data 3 (frequency oo) at the center point of the subcarrier. Subcarrier data SC1 includes eight items of data (9, 10, 11, 12, 13, 14, 15, 0) before and after (−4, +3) data 13 (frequency ω₁) of the center point of the subcarrier. Note that the frequency offset compensation is performed, the sample number of data included in each subcarrier data shifts by +2. In the example of FIG. 3, some signals of subcarrier data SC0 and subcarrier data SC1 overlap. Note that in the present example embodiment, the number of items of data for each subcarrier is set in advance, and the subcarrier data may be identified if the center point of the subcarrier frequency is identified,

The address control unit 11 generates a write address and a read address of data based on the offset amount of the light source frequency and the center point for each subcarrier. The address control unit 11 specifies the generated write address and read address in the storage unit 13. The data written in the storage unit 13 in accordance with the specification by the address control unit 11 is read out from the storage unit 13 in an array in which the offset compensation processing and subcarrier separation processing are collectively performed.

The storage unit 13 is input with a plurality of items of data constituting the FFT data X(ω) that is Fourier-transformed by the Fourier transform device 110. For example, the storage unit 13 is achieved by a memory such as a random access memory (RAM) or a storage device such as a register. The storage unit 13 stores the plurality of items of data constituting the input FFT data X(ω) in the write address specified by the address control unit 11. The plurality of items of data stored in the storage unit 13 is read out in accordance with the read address specified by the address control unit 11. The plurality of items of data stored in the storage unit 13 is offset compensated in accordance with the specification by the address control unit 11, and is separated for each subcarrier and output. In the present example embodiment, subcarrier data SC0 and subcarrier data SC1 are output from the storage unit 13. For example, as preprocessing of subcarrier separation, a configuration for performing serial to parallel conversion processing may be added. In addition, a circuit or processing for compensating for skew of data after parallel conversion may be added.

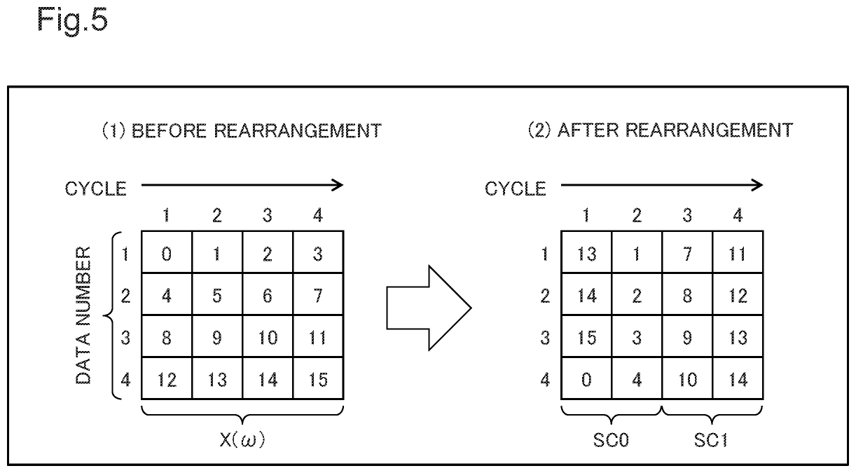

FIG. 5 is a schematic diagram illustrating a situation in which the data constituting FFT data X(ω) input to the storage unit 13 is rearranged from the array before rearrangement (1) to the array after rearrangement (2). The order of data in the array before rearrangement (1) is continuous in the time direction of the output of the Fourier transform device 110. The order of data in the array after rearrangement (2) is continuous in the parallel direction at the same time. In the present example embodiment, the operations of writing and reading data to and from the storage unit 13 are performed in parallel by address control, so that data is rearranged in an array in which the offset compensation processing and subcarrier separation processing are performed. As a result, the FFT data X(ω) is offset compensated and separated for each subcarrier. In the example of FIG. 5, the data of subcarrier data SC0 is rearranged to cycle 1-2 and the data of subcarrier data SC1 is rearranged to cycle 3-4. The array of data constituting the subcarrier data is rearranged in an order in which the processing in the inverse Fourier transform device 120 is easily performed.

The filter processing device 10 outputs subcarrier data separated for each of the plurality of subcarriers. The array of data constituting the subcarrier data is rearranged in an order in which the processing in the inverse Fourier transform device 120 is easily performed. The plurality of items of subcarrier data output from the filter processing device 10 is input to the inverse Fourier transform device 120.

The plurality of items of subcarrier data output from the filter processing device 10 is input to the inverse Fourier transform device 120. The inverse Fourier transform device 120 includes a conversion circuit for each subcarrier. The inverse Fourier transform device 120 performs inverse Fourier transform on the plurality of items of subcarrier data for each subcarrier, and converts the subcarrier data to a signal into the time domain. The inverse Fourier transform device 120 outputs the subcarrier data converted into a signal in the time domain.

### (Operation)

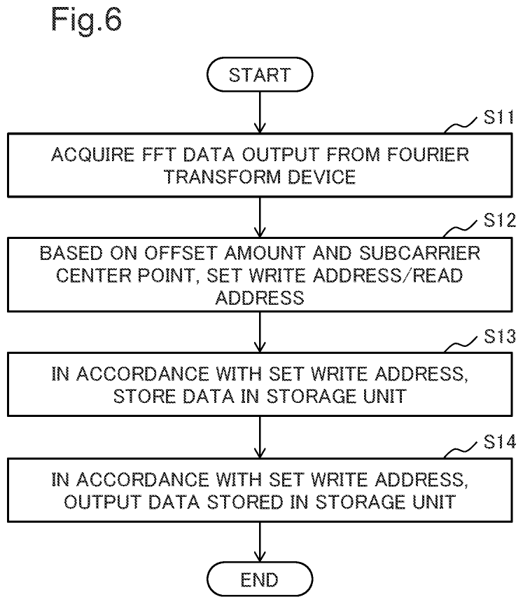

Next, an example of an operation of the filter processing device 10 of the communication system 1 will be described with reference to the drawings. FIG. 6 is a flowchart for illustrating the operation of the filter processing device 10. In the following processing along the flowchart in FIG. 6, the filter processing device 10 will be described as an operation subject.

FIG. 6, first, the filter processing device 10 acquires the FFT data output from the Fourier transform device 110 (step S11).

Next, the filter processing device 10 generates the write address and read address of the FFT data based on the offset amount of the light source frequency and the subcarrier center point for each subcarrier (step S12).

Next, the filter processing device 10 stores data constituting the FFT data in the storage unit 13 in accordance with the set write address (step S13).

Next, the filter processing device 10 outputs the data stored in the storage unit 13 in accordance with the set read address (step S14). The data output in step S14 is subcarrier data that is offset compensated and separated for each subcarrier. The subcarrier data output from the filter processing device 10 is input to the inverse Fourier transform device 120. The subcarrier data input to the inverse Fourier transform device 120 is subjected to inverse Fourier transform for each subcarrier.

### Related Technology 1

Here, related technology 1 of the first example embodiment will be described with reference to the drawings. The related technology is an example in which the offset compensation processing and subcarrier separation processing are separately performed.

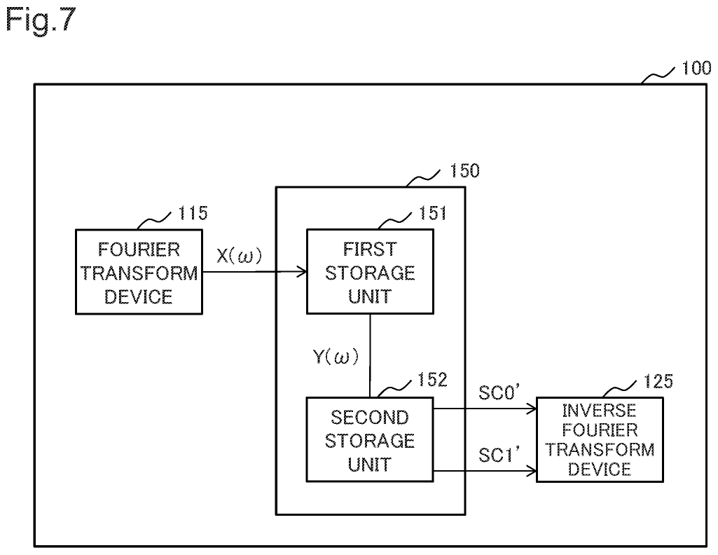

FIG. 7 is a block diagram illustrating an example of a configuration of a communication system 100 of the related technology. The communication system 100 includes a Fourier transform device 115, a filter processing device 150, and an inverse Fourier transform device 125. The filter processing device 150 includes a first storage unit 151 and a second storage unit 152. The filter processing device 150 is connected to the Fourier transform device 115 and inverse Fourier transform device 125. The Fourier transform device 115 has the similar configuration as the Fourier transform device 110 of the first example embodiment. The inverse Fourier transform device 125 has the same configuration as the inverse Fourier transform device 120 of the first example embodiment.

The first storage unit 151 is input with data constituting FFT data X(ω). The first storage unit 151 is a storage unit for offset compensation processing. The data input to the first storage unit 151 is rearranged in accordance with the set offset amount and output. In the example of FIG. 7, the offset compensated data Y(ω) is output from the first storage unit 151.

The second storage unit 152 is input with data constituting the offset compensated data Y(ω). The second storage unit 152 is a storage unit for subcarrier separation. The data input to the second storage unit 152 is rearranged in accordance with the frequency of the center point for each subcarrier and output. In the example of FIG. 7, subcarrier data SC0′ and subcarrier data SC1′ subjected to the subcarrier separation are output from the second storage unit 152 to the inverse Fourier transform device 120. The array of data constituting the subcarrier data is rearranged in an order in which the processing in the inverse Fourier transform device 120 is easily performed. Subcarrier data SC0′ and subcarrier data SC1′ output from the second storage unit 152 are subjected to the inverse Fourier transform processing for each subcarrier in the inverse Fourier transform device 120.

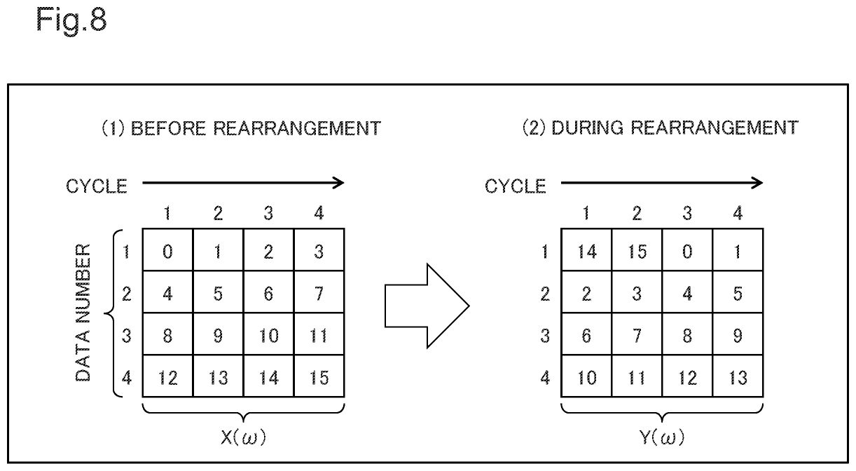

FIG. 8 is a schematic diagram illustrating a situation in which the data constituting FFT data X(ω) input to the first storage unit 151 is rearranged from the array before rearrangement (1) to the array during rearrangement (2). The data array during rearrangement (2) is a data configuration of the offset compensated data Y(ω). The data array during rearrangement (2) is the data array before rearrangement (1) being offset compensated by +2.

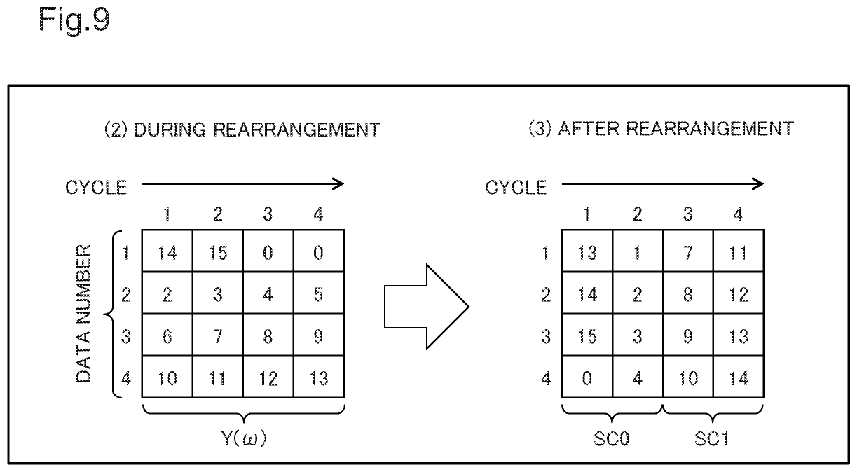

FIG. 9 is a schematic diagram illustrating a situation in which the data constituting the data Y(ω) input to the second storage unit 152 is rearranged from the array during rearrangement (2) to the array after rearrangement (3). The data Y(ω) is separated for each subcarrier. In the example of FIG. 9, the data of subcarrier data SC0 is rearranged to cycle 1-2, and the data of subcarrier data SC1 is rearranged to cycle 3-4. Subcarrier data SC0 includes data 13, data 14, data 15, data 0, data 1, data 2, data 3, and data 4. Subcarrier data SC1 includes data 7, data 8, data 9, data 10, data 11, data 12, data 13, and data 14.

In the method of related technology 1, the first storage unit 151 dedicated to the offset compensation processing and the second storage unit 152 dedicated to the subcarrier separation processing are installed. In addition, in the method of related technology 1, the offset compensation processing and subcarrier separation processing are performed in two steps. In contrast, according to the method of the first example embodiment, the write address and read address of the data constituting the FFT data to the storage unit 13 are controlled in accordance with the specification by the address control unit 11. Therefore, according to the method of the first example embodiment, the offset compensation processing and subcarrier separation processing may be collectively performed without adding a dedicated storage unit for each processing.

As described above, the communication system of the present example embodiment includes the Fourier transform device, the filter processing device, and the inverse Fourier transform device. The Fourier transform device performs Fourier transform on a signal based on the optical signal. The Fourier transform device outputs the Fourier transform data including the plurality of items of data after the Fourier transform to the filter processing device. The filter processing device includes the address control unit and the storage unit. The address control unit specifies, based on the offset amount of a light source frequency and a subcarrier center point for each subcarrier, the write address and read address for the plurality of items of data included in Fourier transform data based on the optical signal. The address control unit specifies the write address and the read address so that compensation for the offset amount and separation of the subcarrier are performed by the same storage unit. In the storage unit, the plurality of items of data is written to the write address specified by the address control unit. In the storage unit, data is read out from the read address specified by the address control unit. The inverse Fourier transform device acquires the plurality of items of data subjected to the offset compensation processing and subcarrier separation processing by the filter processing device. The inverse Fourier transform device performs inverse Fourier transform on the plurality of items of data subjected to the offset compensation processing and subcarrier separation processing.

According to the method of the present example embodiment, the subcarrier separation may be performed without adding a dedicated storage unit by performing addressing so that the offset compensation processing and subcarrier separation processing are performed. In other words, according to the present example embodiment, since the number of storage units is not increased for the subcarrier separation processing, the subcarrier separation processing may be performed while controlling the increase in power consumption. In a general method, writing/reading to/from the storage unit is performed twice. In the method of the present example embodiment, writing/reading to/from the same storage unit only needs to be performed once. Therefore, according to the method of the present example embodiment, the overall processing speed in the filter processing is improved by decreasing the number of times of writing/reading to/from the storage unit.

In an aspect of the present example embodiment, the address control unit specifies the write address and read address so that the compensation for the offset amount and the separation of the subcarrier are collectively performed. According to the present aspect, the offset compensation processing and subcarrier separation processing may be collectively performed by writing/reading data to/from the address specified by the address control unit.

In an aspect of the present example embodiment, the address control unit sets to 0 the value of data rendered unnecessary by the frequency offset compensation processing. According to the present aspect, values of unnecessary data included in the plurality of items of data may be deleted.

### Second Example Embodiment

Next, a communication system according to a second example embodiment will be described with reference to the drawings. An optical signal used for optical communication is subjected to analog digital (AD) conversion and then to Fast Fourier Transform (FFT) conversion. A plurality of processing is performed on the FFT converted signal in the frequency domain. The communication system of the present example embodiment is different from that of the first example embodiment in that processing other than the offset compensation processing and subcarrier separation processing is collectively performed after the offset compensation processing and subcarrier separation processing.

### (Configuration)

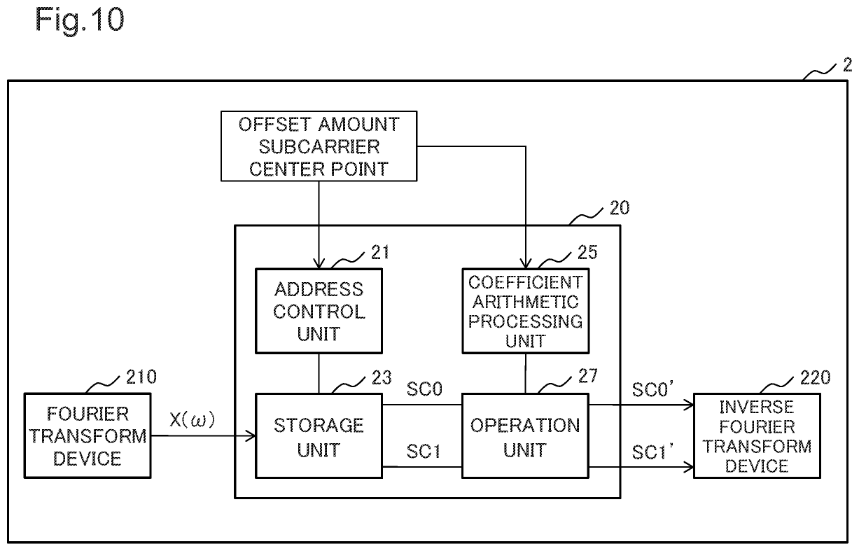

FIG. 10 is a block diagram illustrating of an example of a configuration of a communication system 2 of the present example embodiment. The communication system 2 includes a Fourier transform device 210, a filter processing device 20, and an inverse Fourier transform device 220. The filter processing device 20 is connected to the Fourier transform device 210 and inverse Fourier transform device 220.

The Fourier transform device 210 has the same configuration as the Fourier transform device 110 of the first example embodiment. The Fourier transform device 210 performs FFT conversion on the AD converted signal and converts the signal into frequency domain data (also referred to as FFT data). The Fourier transform device 210 outputs the FFT data to the filter processing device 20.

The filter processing device 20 includes an address control unit 21, a storage unit 23, a coefficient arithmetic processing unit 25, and an operation unit 27. The filter processing device 20 is input with output data (also referred to as FFT data) of the Fourier transform device 210.

The address control unit 21 has the same configuration as the address control unit 11 of the first example embodiment. The address control unit 21 is input with the offset amount of the light source frequency and the center point for each subcarrier (subcarrier center point) input. The offset amount and subcarrier center point may be input via an input device (not shown) or may be set in advance in the address control unit 21. The address control unit 21 generates a write address and a read address of data based on the offset amount of the light source frequency and center frequency for each subcarrier. The address control unit 21 specifies the generated write address and read address in the storage unit 23.

The storage unit 23 has the same configuration as the storage unit 13 of the first example embodiment. The storage unit 23 is input with the plurality of items of data constituting the FFT data X(ω) Fourier-transformed by the Fourier transform device 210. The storage unit 23 stores the plurality of items of data constituting the input FFT data X(O) in the write address specified by the address control unit 21. The plurality of items of data stored in the storage unit 23 is read out in accordance with the read address specified by the address control unit 21. The plurality of items of data stored in the storage unit 23 is offset compensated in accordance with the specification by the address control unit 21, and is separated for each subcarrier and output.

The coefficient arithmetic processing unit 25 calculates a coefficient (also referred to as a compensation factor) of compensation processing (also referred to as other compensation processing) different from the offset compensation processing and subcarrier separation processing. The coefficient arithmetic processing unit 25 calculates a compensation factor for each subcarrier data based on the offset amount and the frequency of the subcarrier center point. The other compensation processing is not particularly limited as long as it depends on the offset amount and the frequency of the subcarrier center point. For example, the other compensation processing includes skew compensation processing of compensating for a shift in arrival time of XY polarized waves or I/Q signals whose phases are orthogonal to each other. For example, the other compensation processing includes normalization processing of correcting variation in accordance with the degree of degradation of each signal value (Xᵢ, X_{q}, Yᵢ, Y_{q}) of the I/Q signal. For example, the other compensation processing includes frequency response adjustment processing of compensating for degradation of frequency response due to manufacturing variations of the reception analog front end and environmental variations or the like. For example, the other compensation processing includes wavelength dispersion compensation processing and spectrum shaping processing. In addition, the coefficient arithmetic processing unit 25 may perform 0 filling processing.

The coefficient arithmetic processing unit 25 is input with the offset amount of the light source frequency and the subcarrier center point. The offset amount and subcarrier center point may be input via an input device (not shown) or may be registered in advance in the coefficient arithmetic processing unit 25. The coefficient arithmetic processing unit 25 calculates a compensation factor related to other processing than the offset compensation processing and subcarrier separation processing based on the offset amount of the light source frequency and the center frequency for each subcarrier. For example, the coefficient arithmetic processing unit 25 calculates the compensation factor for each subcarrier.

Here, an example will be described in which the compensation factor is calculated when there are two subcarriers of subcarrier 0 and subcarrier 1. The offset frequency of the light source compensation is f, the frequency of the subcarrier center point of subcarrier 0 is ω₀, and the frequency of the subcarrier center point of subcarrier 1 is ω₁. In addition, the frequency of a plurality of items of data constituting the FFT data is ω. For example, the coefficient arithmetic processing unit 25 calculates compensation factor C0 of subcarrier data SC0 and compensation factor C1 of subcarrier data SC1 using the following formulae 1 and 2.

$$C 0 = {H}_{1} ( ω - f - {ω}_{0} ) \times {H}_{2} ( ω - {ω}_{0} ) \qquad ( 1 )$$

$$C 1 = {H}_{1} ( ω - f - {ω}_{1} ) \times {H}_{2} ( ω - {ω}_{1} ) \qquad ( 2 )$$

Note that the above formulae 1 and 2 are examples of the compensation factor calculated by the coefficient arithmetic processing unit 25, and are not limiting to the calculation formula of the compensation factor by the coefficient arithmetic processing unit 25. The compensation factor may depend on the offset frequency f of the light source compensation and the frequency ω₀ and ω₁ of the subcarrier center point.

The operation unit 27 performs compensation processing on the subcarrier data using the compensation factor for each subcarrier computed by the coefficient arithmetic processing unit 25. For example, the coefficient arithmetic processing unit 25 performs compensation processing by multiplying the subcarrier data by the compensation factor for each subcarrier.

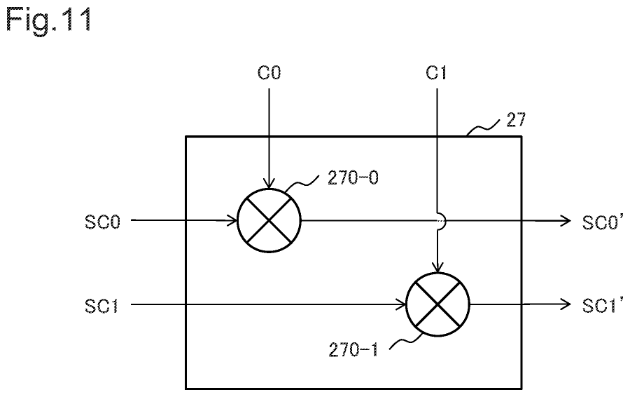

FIG. 11 is a schematic diagram for illustrating multiplication of the compensation factor computed for each subcarrier separately for each subcarrier. The operation unit 27 includes a multiplier 270-0 and a multiplier 270-1. To the multiplier 270-0, a compensation factor C0 of the subcarrier 0 is set. In response to the input of subcarrier data SC0, the multiplier 270-0 multiplies the input subcarrier data SC0 by the compensation factor C0. The multiplier 270-0 outputs subcarrier data SC0′ obtained by multiplying the subcarrier data SC0 by the compensation factor C0. In contrast, to the multiplier 270-1, a compensation factor C1 of the subcarrier 0 is set. In response to the input of the subcarrier data SC1, the multiplier 270-1 multiplies the input subcarrier data SC1 by the compensation factor C1. Multiplier 270-1 outputs subcarrier data SC1′ obtained by multiplying the subcarrier data SC1 by the compensation factor C1.

The filter processing device 20 outputs subcarrier data that is separated for each of the plurality of subcarriers and subjected to other compensation processing. The array of data constituting the subcarrier data is rearranged in an order in which the processing in the inverse Fourier transform device 220 is easily done. The plurality of items of subcarrier data output from the filter processing device 20 is input to the inverse Fourier transform device 220.

The inverse Fourier transform device 220 has the same configuration as the inverse Fourier transform device 120 of the first example embodiment. The inverse Fourier transform device 220 performs inverse Fourier transform on the plurality of items of subcarrier data for each subcarrier, and converts the subcarrier data into a signal in the time domain. The inverse Fourier transform device 220 outputs the subcarrier data converted into the signal in the time domain.

### (Operation)

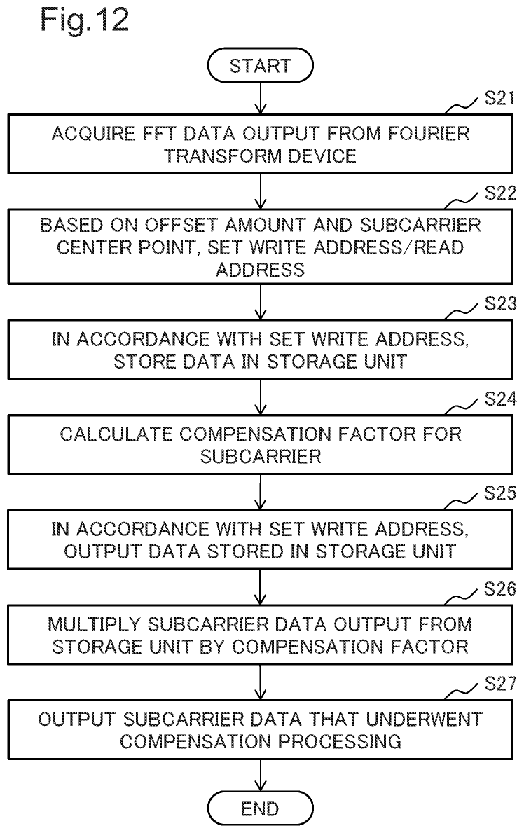

Next, an example of an operation of the filter processing device 20 of the communication system 2 will be described with reference to the drawings. FIG. 12 is a flowchart for illustrating the operation of the filter processing device 20. In the following description along the flowchart in FIG. 12, the filter processing device 20 will be described as an operation subject.

In FIG. 11, first, the filter processing device 20 acquires the FFT data output from the Fourier transform device 210 (step S21).

Next, the filter processing device 20 generates a write address and a read address of the FFT data based on the offset amount of the light source frequency and the subcarrier center point for each subcarrier (step S22).

Next, the filter processing device 20 stores data constituting the FFT data in the storage unit 23 in accordance with the set write address (step S23).

Next, the filter processing device 20 calculates a compensation factor for subcarrier (step S24). The processing in step S24 may be performed after or before step S25.

Next, the filter processing device 20 outputs the data stored in the storage unit 23 in accordance with the set read address (step S25). The data output in step S25 is subcarrier data that is offset compensated and separated for each subcarrier.

Next, the filter processing device 20 multiplies the subcarrier data by the computed compensation factor for each subcarrier (step S26).

Next, the filter processing device 20 outputs the subcarrier data subjected to the compensation processing (step S27). The subcarrier data output from the filter processing device 10 is input to the inverse Fourier transform device 220. The subcarrier data that is input to the inverse Fourier transform device 220 is subjected to inverse Fourier transform for each subcarrier.

### Related Technology 2

Here, related technology 2 of the second example embodiment will be described with reference to the drawings. The related technology is an example in which the compensation processing is separately performed before each processing of the offset compensation processing and subcarrier separation processing.

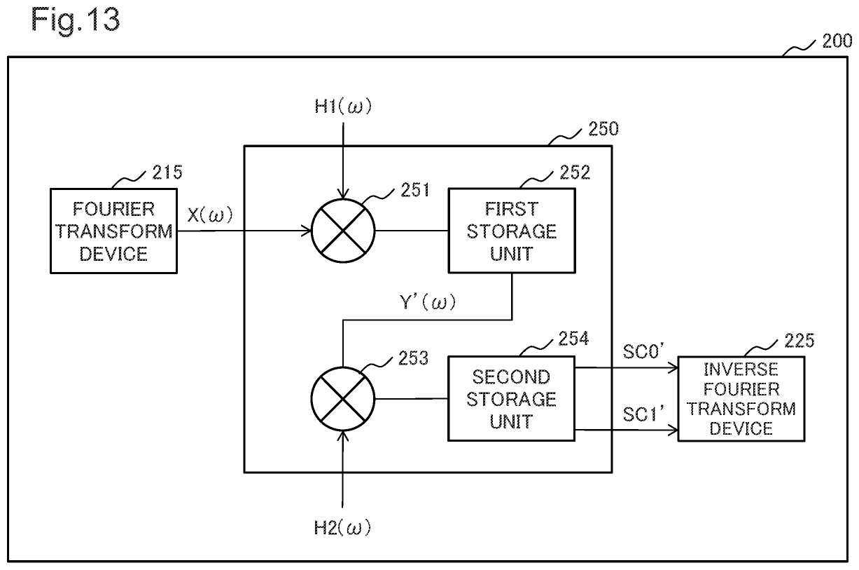

FIG. 13 is a block diagram illustrating an example of a configuration of a communication system 200 of the related technology. The communication system 200 includes a Fourier transform device 215, a filter processing device 250, and an inverse Fourier transform device 225. The filter processing device 250 includes a first multiplier 251, a first storage unit 252, a second multiplier 253, and a second storage unit 254. The filter processing device 250 is connected to the Fourier transform device 215 and inverse Fourier transform device 225. The Fourier transform device 215 has the same configuration as the Fourier transform device 210 in the second example embodiment. The inverse Fourier transform device 225 has the same configuration as the inverse Fourier transform device 220 in the second example embodiment.

The first multiplier 251 is input with data constituting FFT data X(ω). The first multiplier 251 multiplies the data constituting FFT data X(ω) by a compensation factor H1. The first multiplier 251 outputs the data multiplied by the compensation factor H1 to the first storage unit 252.

The first storage unit 252 is input with data multiplied by the compensation factor H1. The first storage unit 252 is a storage unit for offset compensation processing. The data input to the first storage unit 252 is rearranged in accordance with the set offset amount and output. In the example of FIG. 13, the offset compensated data Y′(ω) is output from the first storage unit 252.

The second multiplier 253 is input with the offset compensated data Y′(ω). The second multiplier 253 multiplies the data constituting FFT data X(ω) by the compensation factor H2. The second multiplier 253 outputs the data multiplied by the compensation factor H2 to the second storage unit 254.

The second storage unit 254 is input with the data multiplied by the compensation factor H2. The second storage unit 254 is a storage unit for subcarrier separation. The data input to the second storage unit 254 is rearranged in accordance with the frequency of the center point for each subcarrier and output. In the example of FIG. 13, the subcarrier data SC0′ and subcarrier data SC1′ subjected to the subcarrier separation are output from the second storage unit 254 to the inverse Fourier transform device 220. The array of data constituting the subcarrier data is rearranged in an order in which the processing in the inverse Fourier transform device 220 is easily done. The subcarrier data SC0′ and subcarrier data SC1′ output from the second storage unit 254 are individually subjected to inverse Fourier transform processing in the inverse Fourier transform device 220.

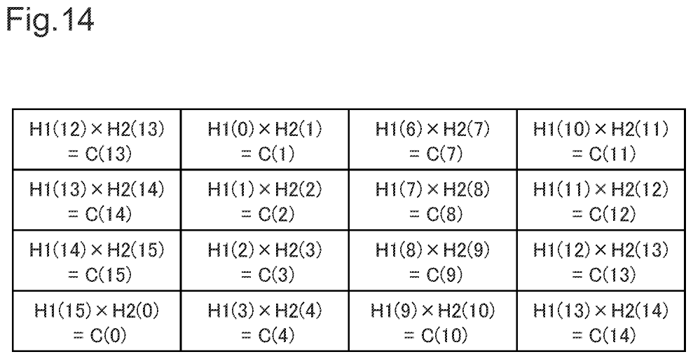

FIG. 14 is a table for illustrating the compensation factor used in the method of the second example embodiment. The example of FIG. 11 collects the compensation factors used for each of 16 items of data constituting the FFT data similar to that of the first example embodiment. The table in FIG. 14 illustrates compensation factors for allowing compensation processing in related technology 2 to be collectively performed. H1(ω) and H2(ω) are compensation factors used for data ω when using the method of related technology 2. C(ω) is a compensation factor used when performing compensation similar to that of related technology 2 when using the method of the second example embodiment. Compensation factor C(13) is a compensation factor of data 13. For example, compensation factor C(13) is obtained by multiplying compensation factor H1(12) and compensation factor H2(13). For example, compensation factor C(14) is obtained by multiplying compensation factor H1(13) and compensation factor H2(14). By using compensation factor C(ω) of FIG. 14, compensation processing similar to that of related technology 2 may be collectively performed.

In the method of related technology 2, necessary compensation processing is performed immediately before each of the frequency offset and subcarrier separation. Therefore, in the method of related technology 2, the compensation processing is performed immediately before each of the frequency offset and subcarrier separation. In contrast, in the method of the second example embodiment, the compensation processing may be collectively performed by multiplying the subcarrier data after the subcarrier separation by the compensation factor computed by the coefficient arithmetic processing unit 25.

As described above, the communication system of the present example embodiment includes the Fourier transform device, the filter processing device, and the inverse Fourier transform device. The Fourier transform device performs Fourier transform on a signal based on the optical signal. The Fourier transform device outputs the Fourier transform data including the plurality of items of data after the Fourier transform to the filter processing device. The filter processing device includes the address control unit, the storage unit, the coefficient arithmetic processing unit, and the operation unit. The address control unit specifies a write address and a read address of the plurality of items of data included in Fourier transform data based on the optical signal based on the offset amount of the light source frequency and the subcarrier center point for each subcarrier. The address control unit specifies the write address and the read address so that compensation for the offset amount and separation of the subcarrier are performed by the same storage unit. In the storage unit, the plurality of items of data is written to the write address specified by the address control unit. In the storage unit, data is read out from the read address specified by the address control unit. Based on the offset amount and subcarrier center point, the coefficient arithmetic processing unit computes a compensation factor used for other compensation processing for each subcarrier. The operation unit collectively performs other compensation processing than the offset compensation processing and subcarrier separation processing on each of the plurality of items of subcarrier data separated for each subcarrier. For example, the operation unit multiplies each of the plurality of items of subcarrier data separated for each subcarrier by the compensation factor computed for each subcarrier by the coefficient arithmetic processing unit. The inverse Fourier transform device acquires the plurality of items of data subjected to the offset compensation processing and subcarrier separation processing by the filter processing device. The inverse Fourier transform device performs inverse Fourier transform on the plurality of items of data subjected to the offset compensation processing and subcarrier separation processing.

According to the method of the present example embodiment, after the offset compensation processing and subcarrier separation processing, other compensation processing than the offset compensation processing and subcarrier separation processing are collectively performed. Therefore, according to the method of the present example embodiment, the circuit scale and the computation procedure may be simplified with respect to other processing to reduce the power consumption.

In an aspect of the present example embodiment, the coefficient arithmetic processing unit computes the compensation factor for each subcarrier using the first compensation factor and second compensation factor. The first compensation factor is a factor used for the first compensation processing before the offset compensation processing. The second compensation factor is a factor used for the second compensation processing before the subcarrier separation processing. For example, the coefficient arithmetic processing unit computes the compensation factor using the first compensation factor depending on the offset amount and subcarrier center point and the second compensation factor depending on the subcarrier center point. According to the present aspect, since the compensation processing before and after the offset compensation processing may be collectively performed, the circuit scale and arithmetic processing may be simplified.

In an aspect of the present example embodiment, the coefficient arithmetic processing unit sets to 0 the value of data rendered unnecessary by the frequency offset compensation processing. According to the present aspect, values of unnecessary data included in the plurality of items of data may be deleted.

### Third Example Embodiment

Next, a communication system according to a third example embodiment will be described with reference to the drawings. A filter processing device of the communication system of the present example embodiment includes a storage unit including a plurality of partial storage units. Hereinafter, an example will be described in which the filter processing device of the present example embodiment is incorporated in the communication system of the first example embodiment. The filter processing device of the present example embodiment may be incorporated in the communication system of the second example embodiment.

### (Configuration)

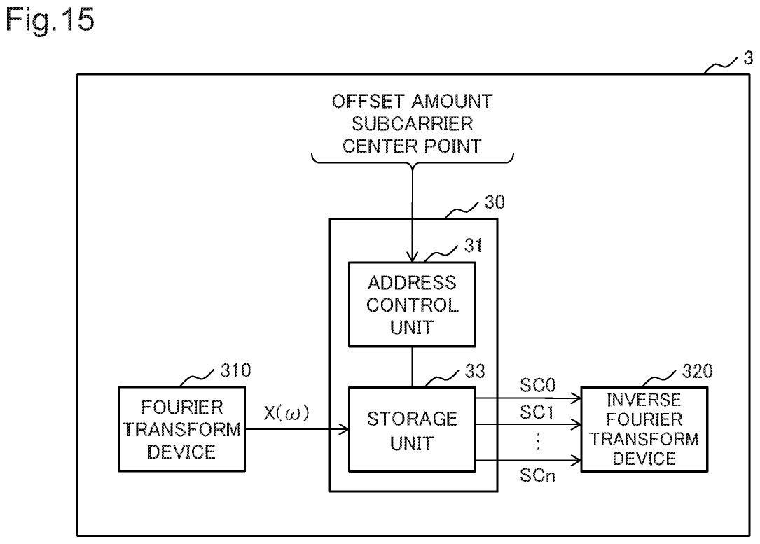

FIG. 15 is a block diagram illustrating of an example of a configuration of the communication system of the present example embodiment 3. The communication system 3 includes a Fourier transform device 310, a filter processing device 30, and an inverse Fourier transform device 320. The filter processing device 30 is connected to the Fourier transform device 310 and inverse Fourier transform device 320.

The Fourier transform device 310 has the same configuration as the Fourier transform device 110 of the first example embodiment. The Fourier transform device 310 performs FFT conversion on the AD converted signal and converts the signal into frequency domain data (also referred to as FFT data). The Fourier transform device 310 outputs the FFT data to the filter processing device 30.

The filter processing device 30 includes an address control unit 31 and a storage unit 33. The filter processing device 30 is input with output data (also referred to as FFT data) of the Fourier transform device 310.

The address control unit 31 is input with the offset amount of the light source frequency and the center point for each subcarrier (subcarrier center point). The offset amount and subcarrier center point may be input via an input device (not shown) or may be set in advance in the address control unit 31. The address control unit 31 outputs the offset amount and subcarrier center point to the storage unit 33. The address control unit 31 may generate a write address and a read address of data to/from the storage unit 33 based on the offset amount of the light source frequency and the center frequency for each subcarrier. In that case, the address control unit 31 specifies the generated write address and read address in the storage unit 33.

The storage unit 33 is input with a plurality of items of data constituting the FFT data X(ω) Fourier-transformed by the Fourier transform device 310. The FFT data X(ω) includes a plurality of items of subcarrier data. The plurality of items of data constituting the FFT data X(ω) is input for each cycle. The storage unit 33 includes a plurality of partial storage units (described below). The plurality of partial storage units are configured in association with cycles. The storage unit 33 stores the plurality of items of data constituting the input FFT data X(ω) in the partial storage unit for each cycle. The plurality of items of data constituting the subcarrier data is input to the storage unit 33 in different cycles since the sample numbers are consecutive. Therefore, the data constituting the subcarrier data is stored in a distributed manner in different partial storage units. When the write address is specified by the address control unit 31, the storage unit 33 stores data in the specified write address.

The plurality of items of data stored in the storage unit 33 is read out from each of the plurality of partial storage units in the order in which the offset compensation and subcarrier separation are performed based on the offset amount and subcarrier center point. The data constituting the subcarrier data is stored in different partial storage units. Therefore, by reading out the plurality of items of data constituting the subcarrier data from each of the plurality of partial storage units, the subcarrier data in which the offset amount is compensated may be separated. When the read address is specified by the address control unit 31, the plurality of items of data stored in the storage unit 33 is read out in accordance with the read address specified by the address control unit 31. As a result, the plurality of items of data stored in the storage unit 33 is offset compensated and separated for each subcarrier and output.

The filter processing device 30 outputs subcarrier data separated for each of the plurality of subcarriers. When the filter processing device 30 is incorporated in the communication system 2 of the second example embodiment, the filter processing device 30 outputs subcarrier data subjected to compensation processing other than the offset compensation and subcarrier separation (also referred to as other compensation processing). The array of data constituting the subcarrier data is rearranged in an order in which the processing in the inverse Fourier transform device 320 is easily done. The plurality of items of subcarrier data output from the filter processing device 30 is input to the inverse Fourier transform device 320. In the example of FIG. 15 schematically illustrates the plurality of items of subcarrier data (SC0, SC1, . . . , SCn) being output from the storage unit 33 (n is a natural number). The plurality of items of subcarrier data may be output serially for each subcarrier or may be output in parallel.

The inverse Fourier transform device 320 has the same configuration as the inverse Fourier transform device 120 of the first example embodiment. The inverse Fourier transform device 320 performs inverse Fourier transform on the plurality of items of subcarrier data for each subcarrier and converts the subcarrier data into a signal in the time domain. The inverse Fourier transform device 320 outputs the subcarrier data converted into the signal in the time domain.

### (Storage Unit)

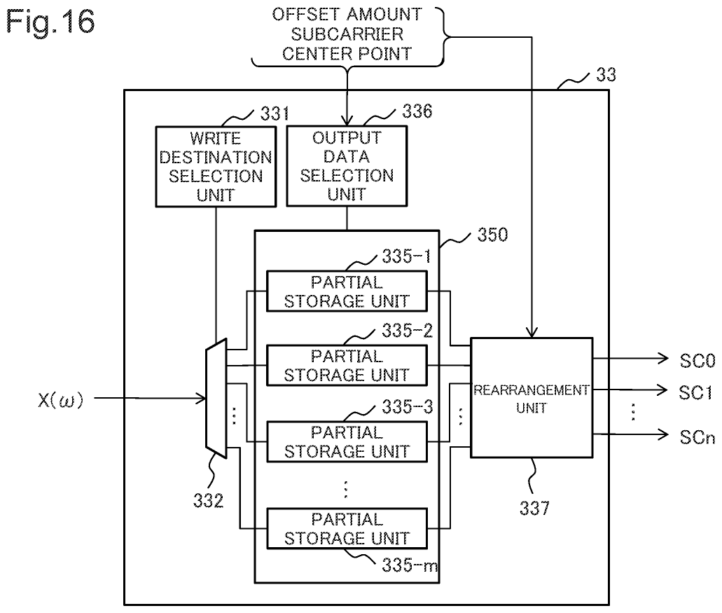

Next, a detailed configuration of the storage unit 33 will be described with reference to the drawings. FIG. 16 is a block diagram illustrating an example of a detailed configuration of the storage unit 33. The storage unit 33 includes a write destination selection unit 331, a first selection unit 332, a plurality of partial storage units 335-1 to m, an output data selection unit 336, and a rearrangement unit 337 (m is a natural number equal to or more than two). The plurality of partial storage units 335-1 to m constitutes a partial storage device group 350. Hereinafter, when a common point of the plurality of partial storage units 335-1 to m is described, each of the plurality of partial storage units 335-1 to m may be referred to as a partial storage unit 335 without being distinguished.

The write destination selection unit 331 outputs to the first selection unit 332 a selection control signal (also referred to as an input control signal) for specifying the partial storage unit 335 as a write destination of the plurality of items of data constituting the FFT data X(ω). The partial storage unit 335 as a write destination of the plurality of items of data constituting the FFT data X(ω) is set for each cycle. For example, the write destination selection unit 331 may be omitted and the address control unit 31 may output the selection control signal.

The first selection unit 332 is input with the plurality of items of data constituting the FFT data X(ω) for each cycle. In accordance with the selection control signal from the write destination selection unit 331, the first selection unit 332 distributes the plurality of items of data to the partial storage unit 335 for each cycle. The first selection unit 332 functions as a distributor. For example, the first selection unit 332 is achieved by a demultiplexer (selector).

Each of the plurality of partial storage units 335-1 to m is configured in association with an input cycle of the plurality of items of data constituting the FFT data X(ω). The plurality of items of data constituting the FFT data X(ω) is sequentially input to the 335 partial storage unit for each cycle. Each of the plurality of partial storage units 335-1 to m stores data of a cycle associated with each of the partial storage units 335-1 to m. For example, the input cycle of the plurality of items of data constituting the FFT data X(ω) is set to 0 to m−1 (m is a natural number equal to or more than two). In this case, the data of cycle 0 is stored in the partial storage unit 335-1. In addition, the data of cycle m−1 is stored in the partial storage unit 335-m.

The plurality of items of data constituting the subcarrier data has consecutive sample numbers. Therefore, the plurality of items of data constituting the subcarrier data is input to different storage units 33 in different cycles. Therefore, the data constituting the subcarrier data is stored in the different partial storage units 335 in a distributed manner. Note that when the number of items of data constituting the subcarrier data exceeds the number of items of data for one cycle, the plurality of items of data constituting the same subcarrier data may be stored in the same partial storage unit 335. When the write address is specified by the address control unit 31, data is stored in the specified write address of the partial storage unit 335.

The output data selection unit 336 is connected to each of the plurality of partial storage units 335-1 to m. Although FIG. 16 shows the output data selection unit 336 being connected to the partial storage device group 350, the output data selection unit 336 is connected to each of the plurality of partial storage units 335-1 to m. Based on the offset amount and subcarrier center point, the output data selection unit 336 outputs a selection control signal (also referred to as an output control signal) that specifies the data to be read out to each of the plurality of partial storage units 335-1 to m. For example, the output data selection unit 336 may be omitted and the address control unit 31 may output the selection control signal.

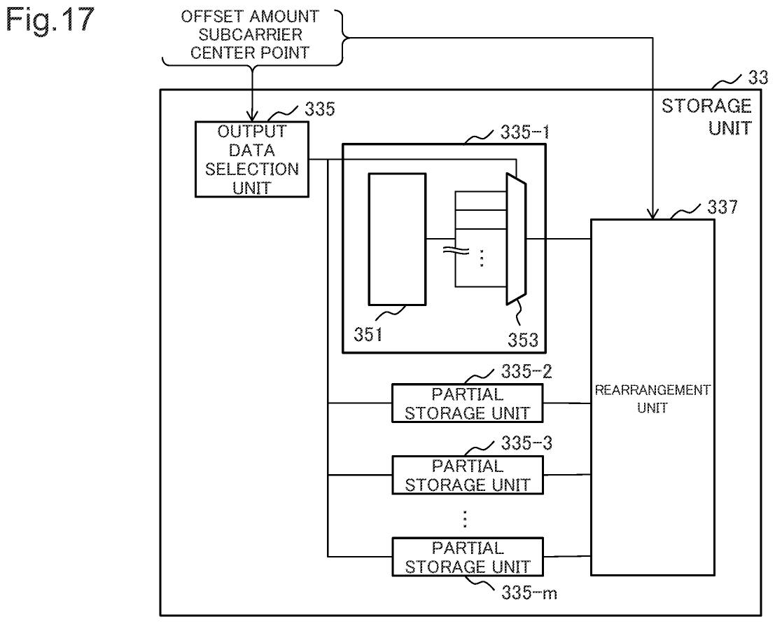

FIG. 17 is a schematic diagram for illustrating an example of an internal configuration of the partial storage unit 335. FIG. 17 only shows the internal configuration of the partial storage unit 335-1 and omits the internal configurations of the other partial storage units 335-2 to m. The partial storage unit 335 includes a storage element array 351 and a second selection unit 353.

The storage element array 351 is a storage structure in which a plurality of storage element is arranged in an array. The plurality of items of data constituting the FFT data X(ω) is stored in the storage element array 351. For example, the partial storage unit 335 is achieved by a storage device such as a memory or a register. In the present example embodiment, a memory is assumed as the partial storage unit 335, but the partial storage unit 335 may be achieved by a storage device other than the memory. For example, the partial storage unit 335 may be achieved by a secondary memory including a hard disk drive, a solid state drive, a magnetic disk, an optical disk, a magneto-optical disk, a flash memory or the like.

In accordance with the selection control signal from the output data selection unit 336, the second selection unit 353 reads the plurality of items of data constituting the subcarrier data from each of the plurality of partial storage units 335-1 to m. The plurality of items of data read out from each of the plurality of partial storage units 335-1 to m in accordance with the selection control signal from the output data selection unit 336 is the data constituting the subcarrier data in which the offset amount is compensated. The second selection unit 353 functions as a multiplexer. For example, the second selection unit 353 is achieved by a multiplexer (selector). The second selection unit 353 may be arranged between the plurality of partial storage units 335-1 to m and the rearrangement unit 337. In that case, the plurality of items of data stored in the plurality of partial storage units 335-1 to m in a distributed manner is read out via the single second selection unit 353.

In accordance with the selection control signal input to the second selection unit 353, data for each subcarrier is read out from each of the plurality of partial storage units 335-1 to m at the same timing. As a result, the plurality of items of data constituting the same subcarrier data is output from each of the plurality of partial storage units 335-1 to m at the same timing. For example, when the plurality of items of data constituting the subcarrier data is a data amount for one cycle, these items of data are output from different partial storage units 335-1 to m at the same timing. For example, when the plurality of items of data constituting the subcarrier data is data amounts for a plurality of cycles, these items of data are output from different partial storage units 335-1 to m at a plurality of consecutive timings. The data output from each of the plurality of partial storage units 335-1 to m in accordance with the selection control signal is output to the rearrangement unit 337.

The rearrangement unit 337 is input with data output from each of the plurality of partial storage units 335-1 to m. The plurality of items of data input to the rearrangement unit 337 are not arranged in the order of arrangement of the subcarrier data. The rearrangement unit 337 rearranges and outputs the plurality of items of input data in the order of arrangement of the subcarrier data. The plurality of items of data output from the rearrangement unit 337 constitutes subcarrier data in which the offset amount is compensated. The subcarrier data (SC0, SC1, . . . , SCn) output from the rearrangement unit 337 is collected for each subcarrier and output to the inverse Fourier transform device 320. The example of FIG. 16 schematically illustrates the plurality of items of subcarrier data (SC0, SC1, . . . , SCn) being output from the rearrangement unit 337 (n is a natural number). The plurality of items of subcarrier data may be output serially for each subcarrier or may be output in parallel. When a configuration for rearranging data is provided between the filter processing device 30 and the inverse Fourier transform device 320, the rearrangement unit 337 may be omitted.

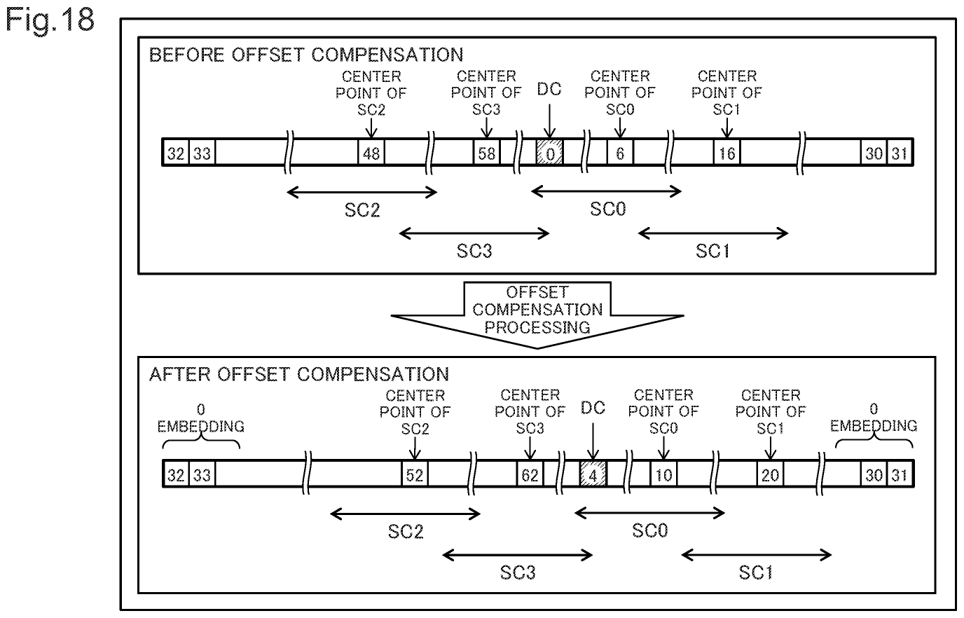

Next, processing by the filter processing device 30 of the present example embodiment will be described with reference to the drawings. FIG. 18 is a schematic diagram for illustrating offset compensation processing. In the example of FIG. 18, 64 items of discrete data (data 0 to 63) constitutes the FFT data X(ω). In the following discussion, when showing the internal configuration of the storage unit 33, a part of the configuration may be omitted.

In the example of FIG. 18, the number of 0 to 63 (also referred to as a sample number) is provided to 64 items of data included in the FFT data X(ω) before being rearranged. Hereinafter, a sample number is provided to each of a plurality of items of data based on the data arrangement in the FFT data X(ω) before being rearranged. The sample number is provided in accordance with the data frequency. Even after the data constituting FFT data X(ω) is rearranged, the sample number provided to the data is maintained as it is. In the example of FIG. 18, the offset amount based on the light source frequency is +4. In FIG. 18, sample numbers of most data are omitted and only sample numbers of some data are shown. In FIG. 18, the arrows indicating the subcarrier data are conceptual and the ends of the arrows do not match the correct sample number.

Before offset compensation (upper stage), the plurality of items of data constituting the FFT data X(ω) is distributed around data 0 of a direct current (DC) component. The FFT data X(ω) includes four items of subcarrier data (SC0, SC1, SC2, SC3). Each of the four items of subcarrier data (SC0, SC1, SC2, SC3) includes 16 items of data. The four items of subcarrier data (SC0, SC1, SC2, SC3) include data overlapping each other. The subcarrier data SC0 before compensation has data 6 as the subcarrier center point and includes 16 items of data (data 62 to 13). The subcarrier data SC1 before compensation has data 16 as the subcarrier center point and includes 16 items of data (data 8 to 23). The subcarrier data SC2 before compensation has data 48 as the subcarrier center point and includes 16 items of data (data 40 to 55). The subcarrier data SC3 before compensation has data 58 as the subcarrier center point and includes 16 items of data (data 50 to 1).

The plurality of items of data after offset compensation (lower stage) is data after offset compensation in the offset compensation processing (+4) based on the light source frequency. The plurality of items of data after offset compensation (lower stage) is distributed around data 4 by the offset compensation processing (+4) based on the light source frequency. The ends (data 32 to 35, 28 to 31) of the plurality of items of data are 0 filled.

The subcarrier data SC0 after offset compensation has data 10 as the subcarrier center point and includes 16 items of data (data 2 to 17). The subcarrier data SC1 after offset compensation has data 20 as the subcarrier center point and includes 16 items of data (data 12 to 27). The subcarrier data SC2 after offset compensation has data 52 as the subcarrier center point and includes 16 items of data (data 44 to 59). The subcarrier data SC3 after offset compensation has data 62 as the subcarrier center point and includes 16 items of data (data 54 to 5).

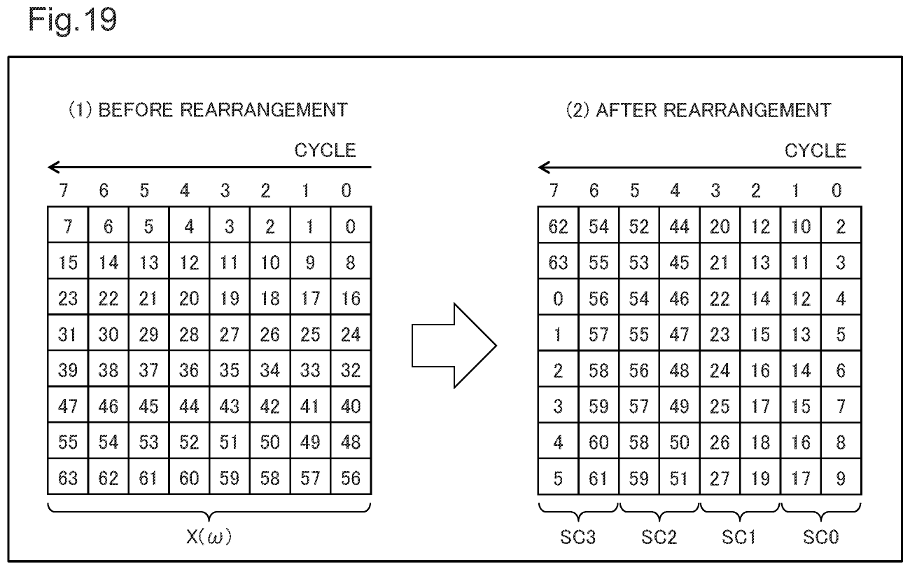

FIG. 19 is a schematic diagram for illustrating an arrangement of the plurality of items of data (data 0 to 63) constituting the FFT data X((O) before and after the offset compensation processing and subcarrier separation processing by the filter processing device 30. FIG. 19 illustrates data arrays (1) before rearrangement and (2) after rearrangement. In 0 to 7 cycles, the storage unit 33 is sequentially input with eight items of data per cycle. In the example of FIG. 19, eight items of data are included per cycle. (2) The data array after rearrangement indicates subcarrier data integrated for each cycle. In the cycles 0 to 1, the subcarrier data SC0 is integrated. In the cycles 2 to 3, the subcarrier data SC1 is integrated. In the cycles 4 to 5, the subcarrier data SC2 is integrated. In the cycles 6 to 7, the subcarrier data SC3 is integrated.

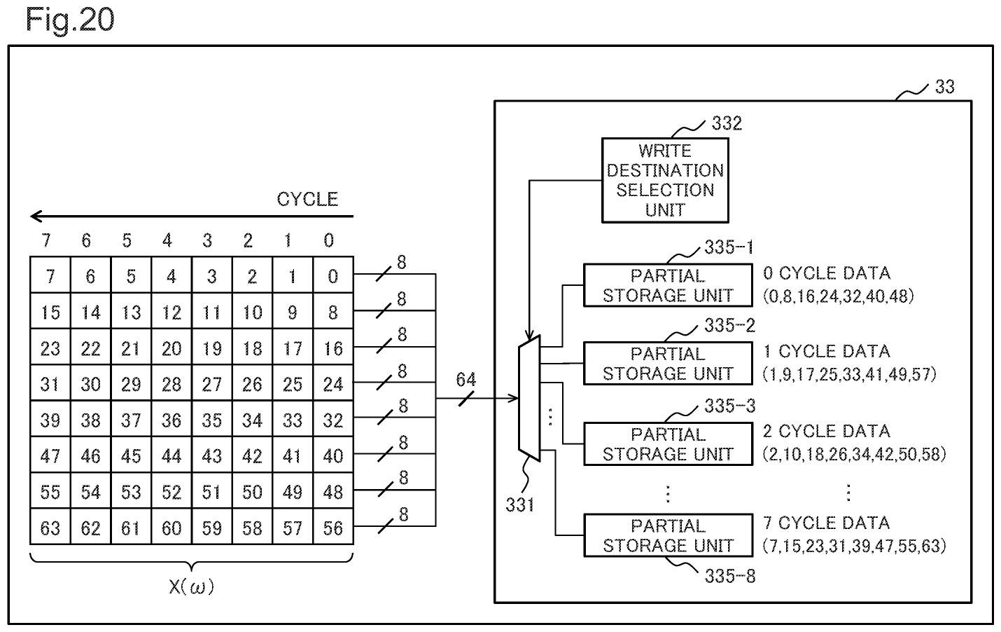

FIG. 20 is a schematic diagram for illustrating an example of writing data into the plurality of partial storage units 335-1 to 8 included in the storage unit 33. The first selection unit 332 is input with the plurality of items of data for each cycle. In accordance with the selection control signal from the write destination selection unit 331, the plurality of items of data input to the first selection unit 332 is distributed to the partial storage unit 335 for each cycle. Data 0, data 8, data 16, data 24, data 32, data 40, data 48, and data 56 input in the zeroth cycle are stored in the partial storage unit 335-1. Data 1, data 9, data 17, data 25, data 33, data 41, data 49, and data 57 input in the first cycle are stored in the partial storage unit 335-2 (data input in the second to sixth cycles is omitted). Data 7, data 15, data 23, data 31, data 39, data 47, data 55, and data 63 input in the seventh cycle are stored in the partial storage unit 335-8.

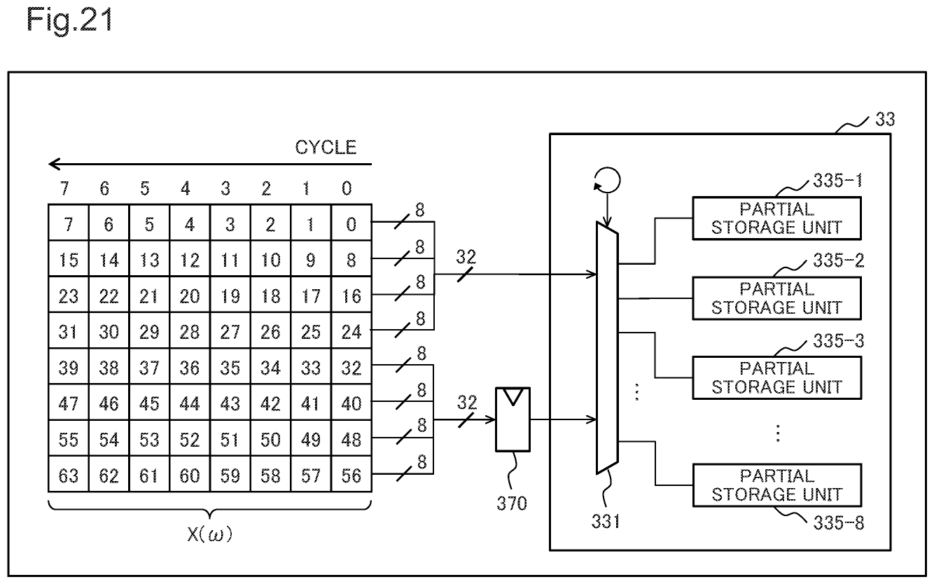

FIG. 21 is a schematic diagram for illustrating another example of writing data into the plurality of partial storage units 335-1 to m included in the storage unit 33. In the example of FIG. 21, the plurality of items of data indicated by the 8×8 matrix is divided into two in the upper and lower stages and input to the partial storage units 335-1 to m for each cycle. The upper data group is directly input to the first selection unit 332. On the input side of the lower data group, a register 370 is arranged. The register 370 functions as a buffer that generates a delay of one cycle. The lower data group is input to the first selection unit 332 with the input timing delayed by one cycle by the register 370. The register 370 may be included in the filter processing device 30 or may be disposed outside the filter processing device 30. For example, the register 370 may be included in the storage unit 33. Although FIG. 21 illustrates an example in which the plurality of items of data is divided into two and input to the storage unit 33 for each cycle, the plurality of items of data may be divided into three or more. The register 370 inserted as shown in FIG. 21 may reduce the amount of data to be written in one cycle, reducing the bit width of the write portion and read portion in the storage unit 33 and partial storage unit 335. This may decrease the areas of the storage unit 33 and partial storage unit 335. An amplifier (not shown) or the like is disposed in the write portion and read portion. If the bit widths of the write portion and read portion may be reduced, the number of amplifiers or the like may be decreased.

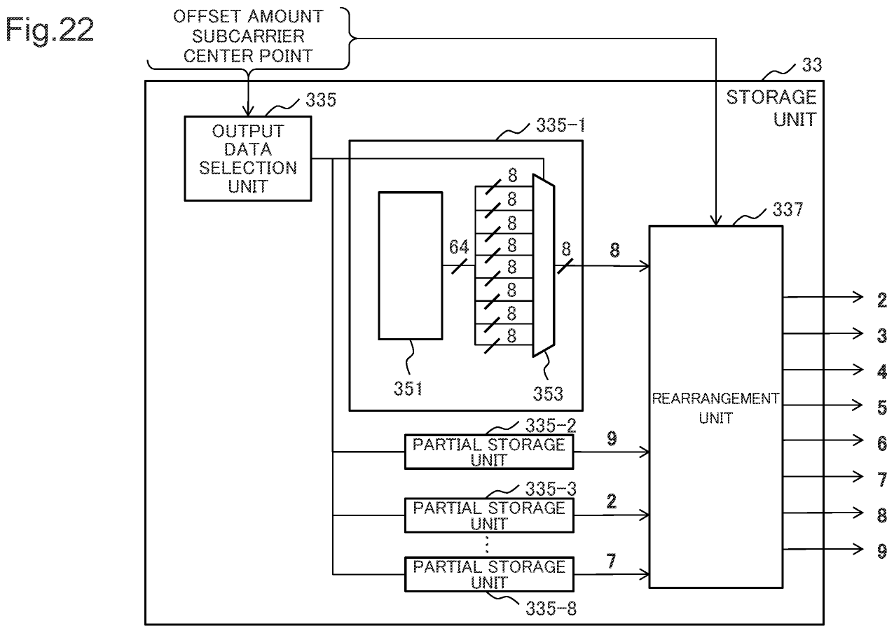

FIG. 22 is a schematic diagram for illustrating an example of reading data from the plurality of partial storage units 335-1 to m included in the storage unit 33. In accordance with the selection control signal from the output data selection unit 336, data is read out from the plurality of partial storage units 335-1 to m. FIG. 22 shows only the internal configuration of the partial storage unit 335-1 and omits the internal configurations of the other partial storage units 335-2 to m. The output data selection unit 336 outputs to each of the plurality of partial storage units 335-1 to m a selection control signal for reading out data in the order of the subcarrier data SC0, the subcarrier data SC1, the subcarrier data SC2, and the subcarrier data SC3.

The subcarrier data SC0 after offset compensation includes 16 items of data (data 2 to 17) centered on the subcarrier center point 10. The partial storage unit 335-1 stores data 8 and data 16. The partial storage unit 335-2 stores data 9 and data 17. The partial storage unit 335-3 stores data 2 and data 10. The partial storage unit 335-4 stores data 3 and data 11. The partial storage unit 335-5 stores data 4 and data 12. The partial storage unit 335-6 stores data 5 and data 13. The partial storage unit 335-7 stores data 6 and data 14. The partial storage unit 335-8 stores data 7 and data 15.

In the example of FIG. 22, first, data 2 to 9 included in the subcarrier data SC0 after offset compensation are read out from the partial storage unit 335-1 to 8. Data 2 to 9 read out from the partial storage unit 335-1 to 8 are rearranged in ascending order by the rearrangement unit 337 and output. Next, data 10 to 17 included in the subcarrier data SC0 after offset compensation are read out from the partial storage unit 335-1 to 8. Data 10 to 17 read out from the partial storage unit 335-1 to 8 are rearranged in ascending order by the rearrangement unit 337 and output. As a result, subcarrier data SC0 after offset compensation is subcarrier separated and output. Subcarrier data SC1, subcarrier data SC2, and subcarrier data SC3 are also offset compensated, subcarrier separated, and output, similarly to subcarrier data SC0.

As described above, the communication system of the present example embodiment includes the Fourier transform device, the filter processing device, and the inverse Fourier transform device. The Fourier transform device performs Fourier transform on a signal based on the optical signal. The Fourier transform device outputs the Fourier transform data including the plurality of items of data after the Fourier transform to the filter processing device. The filter processing device includes the address control unit and the storage unit. The address control unit specifies a write address and a read address of the plurality of items of data included in Fourier transform data based on the optical signal based on the offset amount of the light source frequency and the subcarrier center point for each subcarrier. The address control unit specifies the write address and the read address so that compensation for the offset amount and separation of the subcarrier are performed by the same storage unit. The storage unit includes a plurality of partial storage units in which the plurality of items of data constituting the Fourier transform data is stored. A data group including the data of any of cycles is written to each of the plurality of partial storage units in accordance with an input control signal that allocates the plurality of items of data for each cycle. The data for each subcarrier is sequentially read out from each of the plurality of partial storage units in accordance with the output control signal based on the offset amount and subcarrier center point. The inverse Fourier transform device acquires the plurality of items of data subjected to the offset compensation processing and subcarrier separation processing by the filter processing device. The inverse Fourier transform device performs inverse Fourier transform on the plurality of items of data subjected to the offset compensation processing and subcarrier separation processing.

According to the method of the present example embodiment, the plurality of items of data included in the Fourier transform data is stored in different partial storage units for each cycle. Since the plurality of items of data constituting the subcarrier data has consecutive sample numbers, it is distributed to different partial storage units associated with different cycles. Therefore, according to the method of the present example embodiment, the offset compensation processing and subcarrier separation processing may be performed at the same time by sequentially read out the plurality of items of data constituting the subcarrier data subjected to the offset compensation processing from each of the plurality of partial storage units. Therefore, according to the method of the present example embodiment, the subcarrier separation may be performed without adding a dedicated storage unit for subcarrier separation. In an aspect of the present example embodiment, the storage unit includes the write destination selection unit, the first selection unit, the output data selection unit, and the rearrangement unit. The write destination selection unit outputs the input control signal. The first selection unit is input with the plurality of items of data. The first selection unit distributes the input data to the plurality of partial storage units in accordance with the input control signal. The output data selection unit outputs the output control signal based on the offset amount and the subcarrier center point. The rearrangement unit rearranges and outputs data output from the plurality of partial storage units in accordance with the data configuration of the subcarrier data separated for each subcarrier based on the offset amount and the subcarrier center point. The partial storage unit includes the storage element array and the second selection unit. The storage element array has a structure in which the plurality of storage element is arranged in an array, and stores data. The second selection unit selects and outputs data stored in the storage element array in accordance with output control signal. In the present aspect, the plurality of items of data included the Fourier transform data is stored in different partial storage units for each cycle. In the present aspect, the plurality of items of data constituting the subcarrier data subjected to the offset compensation processing is sequentially read out from each of the plurality of partial storage units, and the plurality of items of read out data is rearranged and output in accordance with the data configuration of the subcarrier data. According to the present aspect, the subcarrier data may be restored by rearranging the plurality of items of data read out from each of the plurality of partial storage units in accordance with the data configuration of the subcarrier data.

A communication system in an aspect of the present example embodiment includes a buffer that delays, by at least one cycle, a timing at which at least one of the plurality of items of data included in the Fourier transform data is input to the filter processing device. According to the present aspect, since the bit width of the write portion and read portion of the storage unit and partial storage unit may be reduced, the areas of the storage unit and partial storage unit may be decreased. In addition, when the write portion and read portion the bit width may be reduced, the number of amplifiers or the like disposed the write portion and read portion may be decreased.

### Fourth Example Embodiment

Next, a filter processing device according to a fourth example embodiment will be described with reference to the drawings. The filter processing device of the present example embodiment has a configuration in which the filter processing device of each example embodiment is simplified. FIG. 15 is a block diagram illustrating an example of a configuration of a filter processing device 40 of the present example embodiment. The filter processing device 40 includes an address control unit 41 and a storage unit 43.

The address control unit 41 specifies a write address and a read address for a plurality of items of data included in the Fourier transform data based on the optical signal based on the offset amount of the light source frequency and the subcarrier center point for each subcarrier. The address control unit 41 specifies the write address and read address so that the compensation for the offset amount and the separation of the subcarrier are performed in the same storage unit 43. In the storage unit 43, the plurality of items of data is written to the write address specified by the address control unit 41. In the storage unit 43, data is read out from the read address specified by the address control unit 41.

According to the filter processing device of the present example embodiment, the subcarrier separation may be performed without adding a dedicated storage unit by performing addressing so that the offset compensation processing and the subcarrier separation processing are performed.

### (Hardware)

Here, a hardware configuration for performing the control and processing according to each example embodiment of the present disclosure will be described using the information processing device 90 in FIG. 16 as an example. The information processing device 90 in FIG. 16 is a configuration example for performing the control and processing of each example embodiment, and not limiting to the scope of the present disclosure. For example, the control and processing according to each example embodiment of the present disclosure may be performed by a micro computer or a micro controller or the like.

As shown in FIG. 16, the information processing device 90 includes a processor 91, a main memory 92, a secondary memory 93, an input/output interface 95, and a communication interface 96. FIG. 16, the interface is abbreviated as an interface (I/F). The processor 91, the main memory 92, the secondary memory 93, the input/output the interface 95, and the communication interface 96 are data communicably connected to each other via bus 98. The processor 91, the main memory 92, the secondary memory 93, and the input/output interface 95 are connected to a network such as the Internet or an intranet via the communication interface 96.

The processor 91 develops a program stored in the secondary memory 93 or the like in the main memory 92. The processor 91 executes the program developed in the main memory 92. In the present example embodiment, a software program installed in the information processing device 90 may be used. The processor 91 executes the control and processing according to the present example embodiment.

The main memory 92 has an area in which a program is developed. A program stored in the secondary memory 93 or the like is developed in the main memory 92 by the processor 91. The main memory 92 is achieved by, for example, a volatile memory such as a dynamic random access memory (DRAM). A non-volatile memory such as a magnetoresistive random access memory (MRAM) may be configured/added as the main memory 92.

The secondary memory 93 stores various data such as programs. The secondary memory 93 is achieved by a local disk such as a hard disk or a flash memory. The various data may be stored in the main memory 92 and the secondary memory 93 may be omitted.

The input/output interface 95 is an interface for connecting the information processing device 90 and a peripheral device based on a standard or a specification. The communication interface 96 is an interface for connecting to an external system or device through a network such as the Internet or an intranet based on a standard and a specification. The input/output interface 95 and communication interface 96 may be shared as an interface connected to an external device.

An input device such as a keyboard, a mouse, and a touch panel may be connected to the information processing device 90 as necessary. These input devices are used to input information and settings. When the touch panel is used as the input device, the display screen of the display device may also serve as the interface of the input device. Data communication between the processor 91 and input device may be mediated by the input/output interface 95.

The information processing device 90 may be provided with a display device for displaying information. When a display device is provided, the information processing device 90 preferably includes a display control device (not shown) for controlling display of the display device. The display device may be connected to the information processing device 90 via the input/output interface 95.

The information processing device 90 may be provided with a drive device. The drive device mediates reading of data and a program from the recording medium, writing of a processing result of the information processing device 90 to the recording medium, and the like between the processor 91 and the recording medium (program recording medium). The drive device may be connected to the information processing device 90 via the input/output interface 95.

The above is an example of a hardware configuration for enabling the control and processing according to each example embodiment of the present invention. The hardware configuration in FIG. 16 is an example of a hardware configuration for performing the control and processing according to each example embodiment, and not limiting the scope of the present invention. A program for causing a computer to execute the control and processing according to each example embodiment is also included in the scope of the present invention. A program recording medium in which a program according to each example embodiment is recorded is also included in the scope of the present invention. The recording medium may be achieved by, for example, an optical recording medium such as a compact disc (CD) or a digital versatile disc (DVD). The recording medium may also be achieved by a semiconductor recording medium such as a universal serial bus (USB) memory or a secure digital (SD) card. The recording medium may be achieved by a magnetic recording medium such as a flexible disk, or another recording medium. When a program executed by the processor is recorded in a recording medium, the recording medium corresponds to a program recording medium.

The components of the wave motion signal processing device of each example embodiment may be combined in any manner. The components of the wave motion signal processing device of each example embodiment may be achieved by software or a circuit.

While the invention has been particularly shown and described with reference to exemplary embodiments thereof, the invention is not limited to these embodiments It will be understood by those of ordinary skill in the art that various changes in form and details may be made therein without departing from the spirit and scope of the present invention as defined by the claims.

Some or all of the above example embodiments may be described as the following supplementary notes, but are not limited to the following.

### (Supplementary Note 1)

A filter processing device including: an address control unit that specifies, based on an offset amount of a light source frequency and a subcarrier center point for each subcarrier, a write address and a read address for a plurality of items of data included in Fourier transform data based on an optical signal; and
a storage unit in which the plurality of items of data are written to the write address specified by the address control unit, and in which the data is read out from the read address specified by the address control unit,
the address control unit specifying the write address and the read address so that
compensation for the offset amount and separation of the subcarrier are performed by the same storage unit.

### (Supplementary Note 2)

The filter processing device according to supplementary note 1, wherein
the address control unit specifies the write address and the read address so that compensation for the offset amount and separation of the subcarrier are collectively performed.

### (Supplementary Note 3)

The filter processing device according to supplementary note 1 or 2, further including a computing unit that collectively performs other compensation processing different from offset compensation processing and subcarrier separation processing for each of a plurality of items of subcarrier data separated for each subcarrier.

### (Supplementary Note 4)

The filter processing device according to supplementary note 3, further including a coefficient computing processing unit that computes, based on the offset amount and the subcarrier center point, a compensation factor used in the other compensation processing for each subcarrier, wherein
the computing unit multiplies the compensation factor computed for each subcarrier by the coefficient computing processing unit by each of the plurality of items of subcarrier data separated for each subcarrier.

### (Supplementary Note 5)

The filter processing device according to supplementary note 4, wherein
the coefficient computing processing unit computes the compensation factor for each subcarrier using a first compensation factor used in a first compensation processing performed before the offset compensation processing and a second compensation factor used in a second compensation processing performed before the subcarrier separation processing.

### (Supplementary Note 6)

The filter processing device according to supplementary note 5, wherein
the coefficient computing processing unit computes the compensation factor using the first compensation factor that depends on the offset amount and the subcarrier center point and using the second compensation factor that depends on the subcarrier center point.

### (Supplementary Note 7)

The filter processing device according to any one of supplementary notes 4 to 6, wherein
one of the address control unit and the coefficient computing processing unit sets to 0 a value of the data rendered unnecessary by the offset compensation processing.

### (Supplementary Note 8)

The filter processing device according to any one of supplementary notes 1 to 7, wherein
the storage unit includes a plurality of partial storage units that stores the plurality of items of data constituting the Fourier transform data, a data group including the data of any of cycles is written to each of the plurality of partial storage unit in accordance with an input control signal that allocates the plurality of items of data for each cycle, and the data for each subcarrier is sequentially read out from each of the plurality of partial storage unit in accordance with an output control signal based on the offset amount and the subcarrier center point.

### (Supplementary Note 9)

The filter processing device according to supplementary note 8, wherein
the storage unit includes a write destination selection unit that outputs the input control signal, a first selection unit configured to be input with the plurality of items of data and distributes the input data to the plurality of partial storage unit in accordance with the input control signal, an output data selection unit that outputs the output control signal based on the offset amount and the subcarrier center point, and a rearrangement unit that rearranges and output the data output from the plurality of partial storage unit in accordance with a data configuration of subcarrier data separated for each subcarrier based on the offset amount and the subcarrier center point, and
the partial storage unit includes a storage element array that has a structure in which a plurality of storage elements are arranged in an array and stores the data, and a second selection unit that selects and outputs the data stored in the storage element array in accordance with the output control signal.

### (Supplementary Note 10)

A communication system including: the filter processing device according to any one of supplementary notes 1 to 9; a Fourier transform device that performs a Fourier transform on a signal based on an optical signal and outputs to the filter processing device Fourier transform data including a plurality of items of data after the Fourier transform; and an inverse Fourier transform device that acquires the plurality of items of data subjected to offset compensation processing and subcarrier separation processing by the filter processing device, and performs an inverse Fourier transform on the plurality of items of data subjected to the offset compensation processing and the subcarrier separation processing.

### (Supplementary Note 11)

The communication system according to supplementary note 10, further including a buffer that delays, by at least one cycle, a timing at which at least one of the plurality of items of data included in the Fourier transform data is input to the filter processing device.

### (Supplementary Note 12)

A filter processing method including:
by a computer, specifying in a storage unit, based on an offset amount of a light source frequency and a subcarrier center point for each subcarrier, a write address and a read address for a plurality of items of data included in Fourier transform data based on an optical signal so that compensation for the offset amount and separation of the subcarrier are performed by a same storage unit;
writing the plurality of items of data to the specified write address of the storage unit; and
reading out the data from the specified read address of the storage unit.

### (Supplementary Note 13)

A program for causing a computer to execute a process of specifying in a storage unit, based on an offset amount of a light source frequency and a subcarrier center point for each subcarrier, a write address and a read address for a plurality of items of data included in Fourier transform data based on an optical signal so that compensation for the offset amount and separation of the subcarrier are performed by a same storage unit;
a process of writing the plurality of items of data to the specified write address of the storage unit; and
a process of reading out the data from the specified read address of the storage unit.

### REFERENCE SIGNS LIST

10, 20, 30, 40 filter processing device
11, 21, 31, 41 address control unit
13, 23, 33, 43 storage unit
25 coefficient arithmetic processing unit
27 operation unit
110, 210, 310 Fourier transform device
120, 220, 320 inverse Fourier transform device
270 multiplier
331 write destination selection unit
332 first selection unit
335 partial storage unit
336 output data selection unit
337 rearrangement unit
350 partial storage device group
351 storage element array
352 second selection unit

What is claimed is:

1. A filter processing device comprising:
a storage in which a plurality of items of data are written to a write address that has specified, and in which the data is read out from a read address that has specified;
a first memory storing instructions; and
a first processor connected to the at first memory and configured to execute the instructions to:
specify, based on an offset amount of a light source frequency and a subcarrier center point for each subcarrier, the write address and the read address for the plurality of items of the data included in Fourier transform data based on an optical signal;
specify the write address and the read address so that compensation for the offset amount and separation of the subcarrier are performed by the same storage.

2. The filter processing device according to claim 1, wherein
the first processor is configured to execute the instructions to
specify the write address and the read address so that compensation for the offset amount and separation of the subcarrier are collectively performed.

3. The filter processing device according to claim 1, wherein
the first processor is configured to execute the instructions to
collectively perform other compensation processing different from offset compensation processing and subcarrier separation processing for each of a plurality of items of subcarrier data separated for each subcarrier.

4. The filter processing device according to claim 3, wherein
the first processor is configured to execute the instructions to
compute, based on the offset amount and the subcarrier center point, a compensation factor used in the other compensation processing for each subcarrier, and
multiply the compensation factor computed for each subcarrier by each of the plurality of items of subcarrier data separated for each subcarrier.

5. The filter processing device according to claim 4, wherein
the first processor is configured to execute the instructions to
compute the compensation factor for each subcarrier using a first compensation factor used in a first compensation processing performed before the offset compensation processing and a second compensation factor used in a second compensation processing performed before the subcarrier separation processing.

6. The filter processing device according to claim 5, wherein
the first processor is configured to execute the instructions to
compute the compensation factor using the first compensation factor that depends on the offset amount and the subcarrier center point and using the second compensation factor that depends on the subcarrier center point.

7. The filter processing device according to claim 1, wherein
the first processor is configured to execute the instructions to
set to 0 a value of the data rendered unnecessary by the offset compensation processing.

8. The filter processing device according to claim 1, wherein
the storage includes a plurality of partial storage-means storages configured to store the plurality of items of data constituting the Fourier transform data,
a data group including the data of any of cycles is written to each of the plurality of partial storages in accordance with an input control signal that allocates the plurality of items of data for each cycle, and
the data for each subcarrier is sequentially read out from each of the plurality of partial storage-means storage in accordance with an output control signal based on the offset amount and the subcarrier center point.

9. The filter processing device according to claim 8, wherein
the storage includes
a first selector configured to be input with the plurality of items of data and distribute the input data to the plurality of partial storage means in accordance with the input control signal,
a second memory storing instructions; and
a second processor connected to the second memory and configured to execute the instructions to:
output the input control signal to the first selector,
output the output control signal based on the offset amount and the subcarrier center point, and
rearrange and output the data output from the plurality of partial storage means in accordance with a data configuration of subcarrier data separated for each subcarrier based on the offset amount and the subcarrier center point, and wherein
the partial storage includes
a storage element array that has a structure in which a plurality of storage elements are arranged in an array and stores the data, and
a second selector configured to select and output the data stored in the storage element array in accordance with the output control signal.

10. A communication system comprising:
the filter processing device according to claim 1;
a Fourier transformer configured to perform a Fourier transform on a signal based on an optical signal and output to the filter processing device Fourier transform data including a plurality of items of data after the Fourier transform; and
an inverse Fourier transformer configured to acquire the plurality of items of data subjected to offset compensation processing and subcarrier separation processing by the filter processing device, and perform an inverse Fourier transform on the plurality of items of data subjected to the offset compensation processing and the subcarrier separation processing.

11. The communication system according to claim 10, further comprising
a buffer configured to delay, by at least one cycle, a timing at which at least one of the plurality of items of data included in the Fourier transform data is input to the filter processing device.

12. A filter processing method executed by a computer, the method comprising:
specifying in a storage, based on an offset amount of a light source frequency and a subcarrier center point for each subcarrier, a write address and a read address for a plurality of items of data included in Fourier transform data based on an optical signal so that compensation for the offset amount and separation of the subcarrier are performed by a same storage;
writing the plurality of items of data to the specified write address of the storage; and
reading out the data from the specified read address of the storage.

13. A non-transitory recording medium storing a program for causing a computer to execute:
a process of specifying in a storage means, based on an offset amount of a light source frequency and a subcarrier center point for each subcarrier, a write address and a read address for a plurality of items of data included in Fourier transform data based on an optical signal so that compensation for the offset amount and separation of the subcarrier are performed by a same storage;
a process of writing the plurality of items of data to the specified write address of the storage; and
a process of reading out the data from the specified read address of the storage.
